(19) United States
(12) Patent Application Publication
(10) Pub. No.: US 2024/0421043 A1
(43) Pub. Date: Dec. 19, 2024

(54) SUBSTRATE PROCESS FLOW FOR ENABLING SUBSTRATE TO DIE HYBRID BONDING

(71) Applicant: Intel Corporation, Santa Clara, CA (US)

(72) Inventors: Kristof Darmawikarta, Chandler, AZ (US); Srinivas Venkata Ramanuja Pietambaram, Chandler, AZ (US); Ji Yong Park, Chandler, AZ (US); Kyu Oh Lee, Chandler, AZ (US); Sheng Li, Gilbert, AZ (US); Gang Duan, Chandler, AZ (US); Sameer Paital, Chandler, AZ (US)

(21) Appl. No.: 18/211,455

(22) Filed: Jun. 19, 2023

(51) Int. Cl. H01L 23/495; H01L 21/768

(52) U.S. Cl. CPC H01L 23/49513; H01L 21/76873; H01L 21/76877

(57) ABSTRACT

Various embodiments disclosed relate to methods of making hybrid bonds for semiconductor assemblies, such as including substrate, semiconductor dies, and/or interconnects. The present disclosure includes a hybrid bond assembly having a via and a dielectric layer, each of the via and the dielectric layer bonding two or more components to each other.

### TECHNICAL FIELD

Embodiments described herein generally relate to electrical interconnections and interconnect methods. Specific examples include electrical interconnections between substrates and semiconductor dies.

### BACKGROUND

For various semiconductor package designs, pitch bump scaling can be used to help shrink the overall package size. It is desired to have electrical connections and methods that address these concerns, and other technical challenges.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 illustrates a cross-sectional view of a semiconductor package assembly having a hybrid bonded substrate in an example.

FIGS. 2A to 2G illustrate a method of hybrid bonding in an example.

FIGS. 3A to 3H illustrate a method of hybrid bonding in an example.

FIGS. 4A to 4F illustrate a method of bonding a semiconductor package substrate to a semiconductor die in an example.

FIG. 5 illustrates a system level diagram, depicting an example of an electronic device in an example.

### DETAILED DESCRIPTION

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

Discussed herein is a method of forming substrate to silicon die electrical connections using hybrid bonding techniques. Hybrid bonding combines embedded metal (such as copper (Cu)) with dielectric bonds (such as silicon oxide (SiOx)), to form permanent bonds. Hybrid bonding enables and increased power, higher bandwidth, and signal integrity.

Such hybrid bonds techniques and methods can be used to electrically connect a semiconductor die, such as a silicon integrated circuit (IC), while maintaining a scaled interconnection size, such as solder bump interconnects with a pitch below 40 microns.

Advanced and complex packaging require interconnects to electrically couple components such as semiconductor dies, substrate, and other components. As package sizes shrink and the complexity of various IC packages increases, different types of interconnects have needed to be developed. Such interconnects should maintain signal integrity while processing a larger volume of data. However, as devices shrink and more components are added into semiconductor packages to store, move, and process data, additional inputs and outputs (I/Os) are desired. For this reason, connects such as solder balls and microbumps should be appropriate scaled to provide the desired number of interconnects while maintaining signal integrity.

In particular, microbumps can provide vertical interconnects, such as between chips, or between dies and package components such as substrates. Microbumps can, for example, include small copper bumps on dies. Such bumps can range in size from 40 micron pitches, down to 20 micron or 10 micron pitches. In particular, with multi-chip monolithic packaging architectures, bridge interconnects benefit from bump pitch scaling, such as bump pitches of less than 40 microns. Such smaller bump pitches can, however, create challenges with reliability of solder joints when a diminished assembly process window times. One approach to address this challenge is a top die first process, but this is not a monolithic approach; instead, it is a carrier-based process flow where the chiplets are reconstituted on a carrier in a face-up configuration, and bridges are attached on exposed pads. However, in applications where the top die chiplets are more expensive, this top die first process is undesirable.

Discussed herein is a method of using hybrid bonding to connect substrates to silicon die. These methods of forming interconnects with smaller bump pitches can include using a hybrid bonding process to form interconnects between substrate and silicon die. Two approaches are discussed, including a monolithic approach and a carrier-based or coreless approach. These methods allow for efficient and effective use of smaller bump pitch (e.g., less than 40 microns), while maintaining solder joint integrity. These methods can additionally allow for good electrical connection.

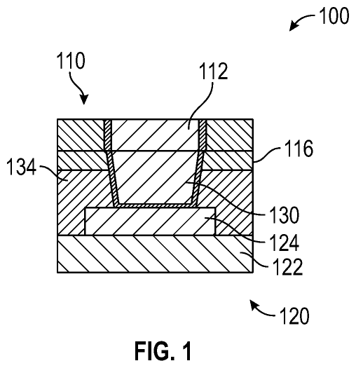

FIG. 1 illustrates a cross-sectional view of a semiconductor package assembly interconnect 100 using hybrid bonding in an example. The hybrid bond includes both a dielectric material and embedded metal to form interconnections. The embedded metal contains a recess to allow for formation of the hybrid bond, because during bonding heat forces the metal together as it expands more than the oxide, causing it to bond. In FIG. 1, the interconnect 100 can have a die pad side 110 and a substrate side 120, with the via 130 extending therebetween. On the substrate side 120 can be the substrate 122 and substrate side copper pad 124. On the die side 110 can be a die side copper pad 112. The via 130 extending between the die pad side 110 and the substrate side 120. The hybrid bond can include solder resist layer 134, via 130, and thin film dielectric layer 116. The interconnect 100 can be, for example, a first level interconnect (FLI).

The via 130 can be made of a metal (e.g., copper or nickel) and dielectric material to secure a semiconductor die on the die side 110 to the substrate 122 on the substrate side 120. The use of a metal or metallic material in conjunction with surround dielectric material allows for a beneficial hybrid bond. Here, the via 130 relies on a copper to copper direct bonding surrounded by dielectric material. For example, the copper pads 112, 124, and the via 130, can form such copper to copper bonds. When a semiconductor die is attached to the interconnect 100, the die bonds with the dielectric material (e.g., thin film dielectric layer 116). During production, the hybrid bond is formed when temperature is increased and the copper pads 112, 124, and via 130, begin to expand towards each other. When the copper pads 112, 124, touch the via 130, a bond is formed therebetween, forming metal-metal bonds. The embedded metallic pads allow for such a hybrid bond.

The die side copper pad 112, the substrate side copper pad 124, and the via 130 can be made of copper metal in this example. In other examples, the pads and bond can be made of another appropriate metal for metal-metal bonds in a hybrid bonding scheme.

The solder resist layer 134 can reside on the substrate 122 and at least partially encapsulate the substrate side copper pad 124. The solder resist layer 134 can be an organic dielectric material. In some cases, the layer 134 can be an epoxy base. The substrate 122 can be a standard semiconductor package substrate, such as a printed circuit board or other appropriate substrate material.

The thin film dielectric layer 116 can be a material that allows for hybrid bonding, such as a silicon based thin film. Examples can include a silicon based dielectric or combinations of silicon based thin films that may include carbon, silicon carbon nitride, or oxynitride. In some cases, this can be an organic material. This hybrid bonding in the interconnect 100 includes metal on metal (e.g., Cu—Cu) direct bonding surrounded by a dielectric to dielectric bonding formed with a thin film, such as SiOx, SiNx, or SiCxNy thin film.

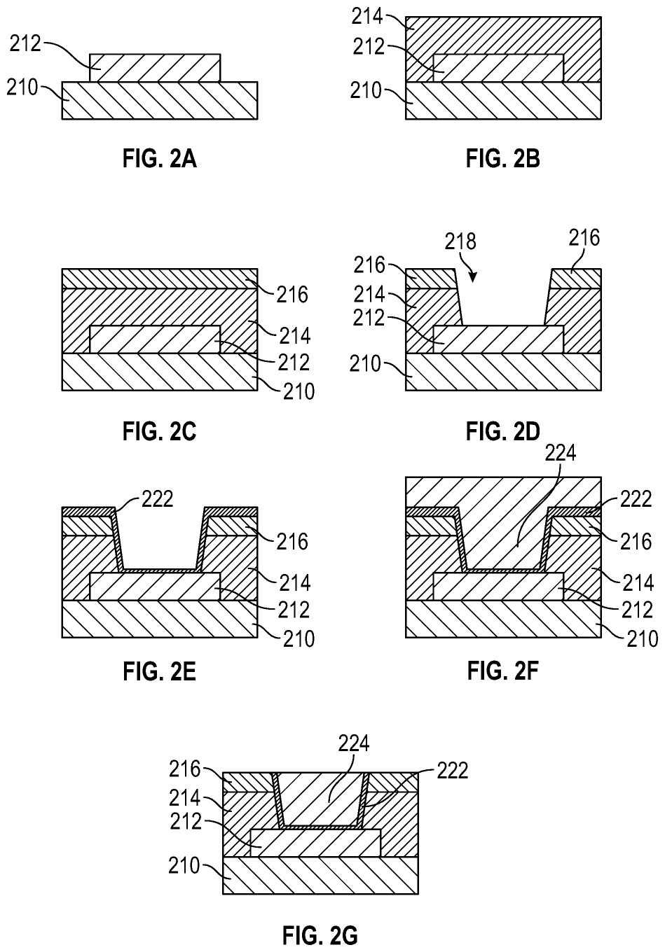

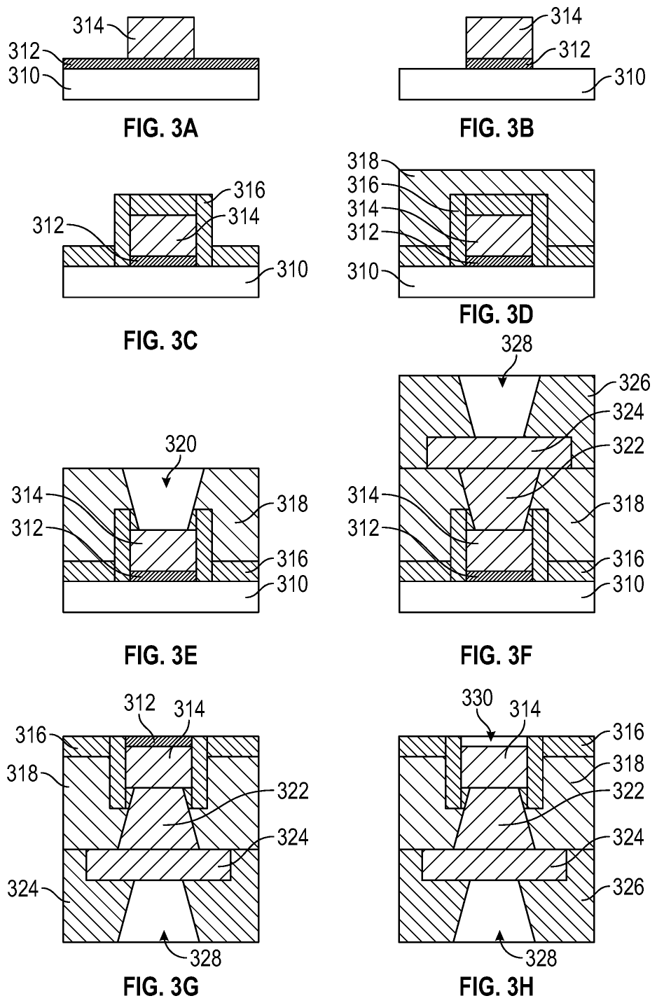

FIGS. 2A to 2G and 3A to 3H depict two different process flow diagrams for production of hybrid bonds in such a substrate to die interconnect. While the method depicted in FIGS. 2A to 2G is a monolithic approach, the method depicted in FIGS. 3A to 3H is a coreless approach. Both methods can be leveraged to product substrate-to-die type hybrid bonds, such as the example bond shown in FIG. 1 above.

FIGS. 2A to 2G illustrate a method 200 of producing an interconnect 205 for hybrid bonding in an example. The method 200 can be used, for example, with a monolithic substrate that may include complex bridges or interconnects embedded in various semiconductor substrate layers. Here, the use of copper pads that are slightly recessed with respect to surrounding thin film material can be used to create hybrid bonds.

The substrate 210 can be a monolithic substrate, that is, the substrate 210 can be built on or with other layers embedded therein, such as metal and organic dielectric layers. For example, bridge interconnects or other multi-layer structures may be incorporated into the substrate 210. A substrate core material can be included in such a monolithic substrate. Here, the hybrid bond can be built on a first layer interconnect (FLI) side of the substrate 210.

First, in FIG. 2A, a first copper pad 212 is deposited on the substrate 210. The substrate 210 itself can be an epoxy, or an organic-based dielectric material, in an example. In FIG. 2B, a solder resist layer 214 is applied over the first copper pad 212 on the substrate 210. The solder resist layer 214 can be, for example, an organic dielectric layer. In FIG. 2C, a thin film layer 216 is deposited on top of the dielectric layer 214. Here, the thin film layer 216, which is a thin film dielectric, is deposited on the organic dielectric. In an example, the thin film can be a silicon nitride or oxide, which can act as a bonding layer. The thin film layer is deposited on to the final surface insulator layer (e.g., solder resist material). In some cases, multiple layers can be deposited. Such layers can be deposited, for example, by selective deposition, atomic-layer deposition, chemical vapor deposition, physical vapor deposition, or other appropriate deposition techniques.

FIG. 2D, a cavity 218 is laser drilled through the thin film layer 216 and the solder resist layer 214. The cavity 218 can be, for example, a laser via, drilled to create an opening for electrical connection. In an example, a single damascene process, via filling and planarization, can be used to create the recess for filling with copper. The recess depth can be controlled during this step to provide the hybrid bonding field.

FIG. 2E, a sputter seed layer 222 can be deposited on the cavity 218. In an example, electrolytic copper plating can be used to fill the cavity 218. This can be done through a sputter technique. FIG. 2F, the copper bond 224 can be deposited into the cavity 218, such as through non-patterned plating. The surface of the cavity 218 can also be overlayered with copper. FIG. 2G, the copper bond 224 can then be planarized. Copper chemical mechanical polishing (Cu CMP) can be used to ensure an amount of recess in the copper such that the copper bond 224 does not sit flush with the top of the interconnect 205.

The recess in the copper bond 224 can allow for hybrid bonding of the copper bond 224 and the thin film layer 216 with a semiconductor die. When the interconnect 205 is used to form a hybrid bond (such as with a semiconductor die), the thin film layer 216 bonds first to the semiconductor die at a copper pad. When heated, the copper bond 224 and a corresponding copper pad on a semiconductor die form a copper-copper bond. This can occur because the copper material expands vertically with heat into the gap between the two, to allow formation of a copper-copper joint. The depth of the gap allows this to occur and formation of such a hybrid bond, where both the copper and the thin film layer form the bond with the corresponding semiconductor die.

FIGS. 3A to 3H illustrate a method of hybrid bonding in an example. Here, a carrier or coreless process is shown, using an initial carrier flatness for controlling depth of the copper recess used in creating a hybrid bond. In this example method, seed, adhesion, or barrier layer(s) can be used to control the final copper recess depth. Such a layer can be made of a etch selective material to allow removal at the end of the process.

First, in FIG. 3A, a carrier 310 is used with the etch material 312. A first copper pad 314 is deposited on the etch material 312. The etch material 312 can be, for example a, seed, adhesion, or barrier layer, that is selectively removable relative the copper. For example, the material can be a titanium sputtered layer. This layer will be removed at the end of the process, and thus can be composed of elements that have high etch selective against the copper and the dielectric. The use of such as layer can help to control the recess depth of the copper.

Next, shown in FIG. 3B, the first copper pad 314 and the etch material 312 are etched to a desired size and shape. Subsequently, shown in FIG. 3C, a thin film layer 316 is deposited on to the first copper pad 314. The thin film layer 316 can be a dielectric deposition, such as a nitiride or oxide layer.

At FIG. 3D, a solder resist material 318 is deposited over the thin film layer 316. A recess 320 for a copper via 322 can be made in the solder resist material 318 (see FIG. 3E). This recess 320 can be filled with copper to create the copper via 322. A second copper pad 324 can then be deposited onto the surface of the copper via 322 shown in FIG. 3F. In an example, the method of FIGS. 3A to 3F can be repeated multiple times, such as to build up multiple layers. Once the desired number of layers have been built up, it can be detached form the carrier 310.

Here, another solder resist or dielectric layer 326 can be deposited over the second copper pad 324. The assembly can then be flipped as needed (see FIG. 3G) and the etch material 312 layer can be removed (FIG. 3H). Once the etch material 312 is removed, a recess 330 over the first copper pad 314 can be leveraged to allow a hybrid bond. The initial carrier 310 flatness can be used to control creation of the recess 330. The amount and type of the etch material 312 can be tailored to create a desired recess 330 depth over the first copper pad 314. The prepared assembly with the copper pad 314, recess 330, and surrounding thin film layer 316, can be used to form a hybrid bond, such as with a semiconductor die.

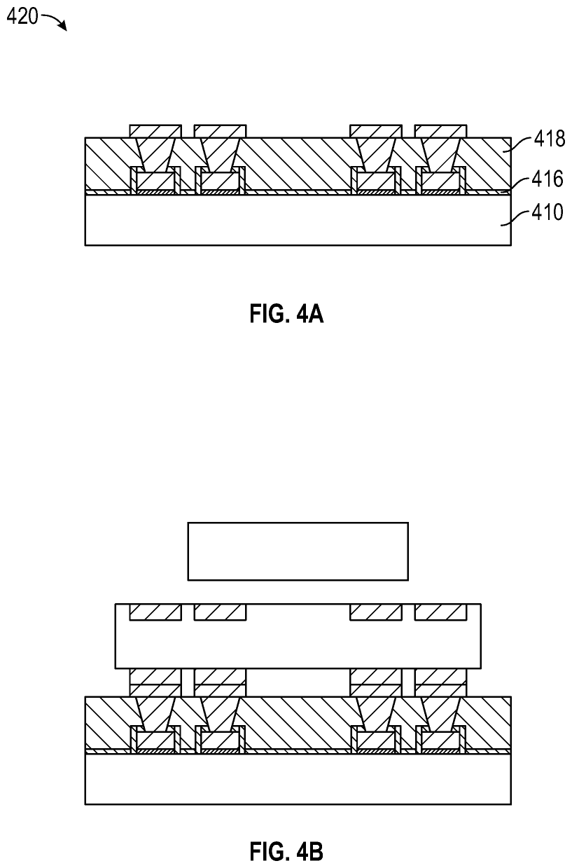

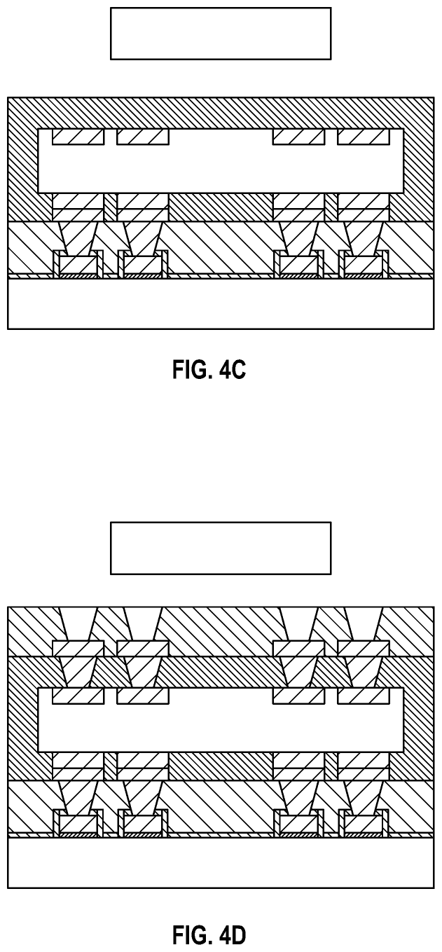

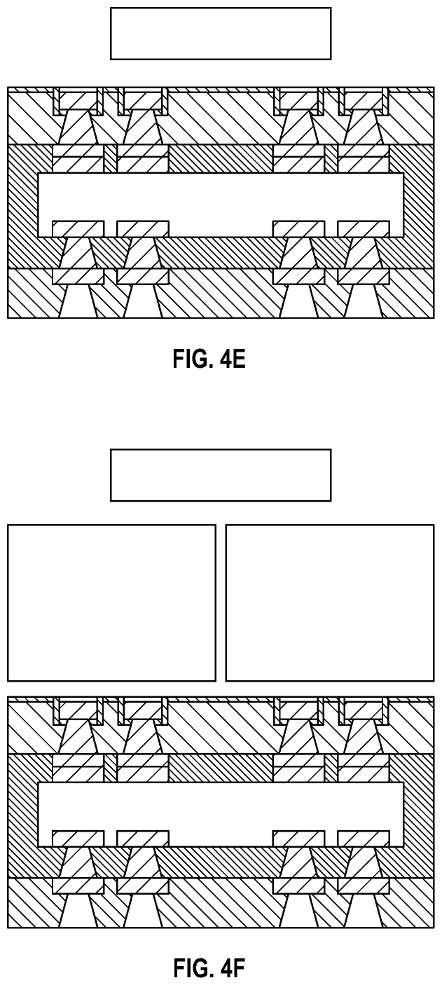

FIGS. 4A to 4F illustrate a method of hybrid bonding a semiconductor package substrate to a semiconductor die in an example. The example hybrid bond structures shown and discussed with reference to FIGS. 1 to 3H can be used, for example, in the methods of FIGS. 4A to 4F, to attach one or more semiconductor dies to a substrate or other interconnector. Shown in FIGS. 4A to 4F is an example process of using a coreless method (such as that discussed with reference to FIGS. 3A to 3H) to attach a bridge interconnect 450 and two semiconductor dies 452, 454, to an assembly.

Shown in FIG. 4A, a carrier 410 with etch material 412 can be used. Here, the copper via 420 have been formed, amongst the solder resist material 418, with the thin film layer 416, on the carrier 410. The copper via 420 and surrounding materials and layers can be built up as discussed above with reference to FIGS. 3A to 3H.

In FIG. 4B, a bridge interconnect die 450 is attached to the copper via 420 on a first side 422. Copper pads 424 on the first side 422 can be used to attach the bridge interconnect 450. The bridge interconnect 450 can, for example, be an interconnect, interposer, or other bridge component, such as a silicon-based bridge with routing therein, so as to allow electrical connection between different components. The bridge interconnect 450 can include multiple routings and via as desired. In an example, a solder attachment can be done between copper pads on the bridge interconnect 450 and the copper pads 424.

In FIG. 4C, the bridge interconnect 450 can be encapsulated, such as with a mold material. Subsequently, in FIG. 4D, additional layers can be built above the bridge interconnect 450. For example, additional layers of dielectric material 456 can be deposited, and additional openings 458 for via, such as copper via, can be made. As desired, additional via, pads, and layers can be built up.

In FIG. 4E, preparation for hybrid bonds can be done before attachment of dies 452, 454. Here, the carrier 410 can be removed to expose the thin film layer 416 and etch material 412. Once exposed, the etch material 412 can be removed to provide recesses 430 in copper via 420 to allow for hybrid bonding.

In FIG. 4F, the two dies 452, 454, can be attached to the copper via 420 through hybrid bonding. The dies 452, 454, can bond first to the thin film layer 416, and subsequently to copper from the copper via 420. The copper can vertically expand when heated to fill the recesses 430 and create a bond between metallic pads on the dies 452, 454, and the copper via 420.

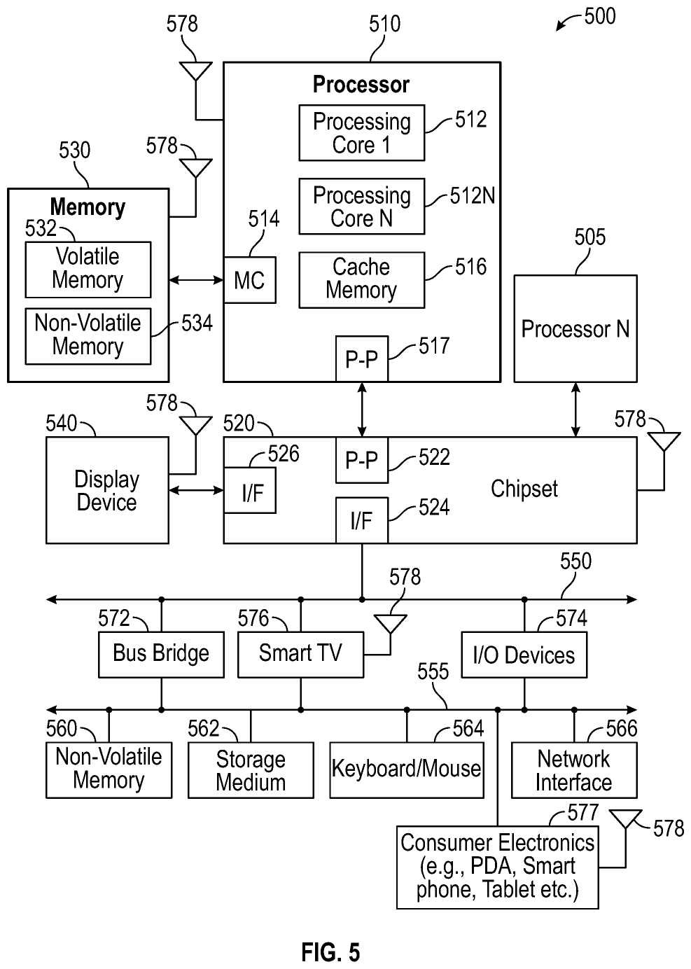

FIG. 5 illustrates a system level diagram, depicting an example of an electronic device (e.g., system) that may include a hybrid bond assembly and/or methods described above. In one embodiment, system 500 includes, but is not limited to, a desktop computer, a laptop computer, a netbook, a tablet, a notebook computer, a personal digital assistant (PDA), a server, a workstation, a cellular telephone, a mobile computing device, a smart phone, an Internet appliance or any other type of computing device. In some embodiments, system 500 includes a system on a chip (SOC) system.

In one embodiment, processor 510 has one or more processor cores 512 and 512N, where 512N represents the Nth processor core inside processor 510 where N is a positive integer. In one embodiment, system 500 includes multiple processors including 510 and 505, where processor 505 has logic similar or identical to the logic of processor 510. In some embodiments, processing core 512 includes, but is not limited to, pre-fetch logic to fetch instructions, decode logic to decode the instructions, execution logic to execute instructions and the like. In some embodiments, processor 510 has a cache memory 516 to cache instructions and/or data for system 500. Cache memory 516 may be organized into a hierarchal structure including one or more levels of cache memory.

In some embodiments, processor 510 includes a memory controller 514, which is operable to perform functions that enable the processor 510 to access and communicate with memory 530 that includes a volatile memory 532 and/or a non-volatile memory 534. In some embodiments, processor 510 is coupled with memory 530 and chipset 520. Processor 510 may also be coupled to a wireless antenna 578 to communicate with any device configured to transmit and/or receive wireless signals. In one embodiment, an interface for wireless antenna 578 operates in accordance with, but is not limited to, the IEEE 802.11 standard and its related family, Home Plug AV (HPAV), Ultra Wide Band (UWB), Bluetooth, WiMax, or any form of wireless communication protocol.

In some embodiments, volatile memory 532 includes, but is not limited to, Synchronous Dynamic Random Access Memory (SDRAM), Dynamic Random Access Memory (DRAM), RAMBUS Dynamic Random Access Memory (RDRAM), and/or any other type of random access memory device. Non-volatile memory 534 includes, but is not limited to, flash memory, phase change memory (PCM), read-only memory (ROM), electrically erasable programmable read-only memory (EEPROM), or any other type of non-volatile memory device.

Memory 530 stores information and instructions to be executed by processor 510. In one embodiment, memory 530 may also store temporary variables or other intermediate information while processor 510 is executing instructions. In the illustrated embodiment, chipset 520 connects with processor 510 via Point-to-Point (PtP or P-P) interfaces 517 and 522. Chipset 520 enables processor 510 to connect to other elements in system 500. In some embodiments of the example system, interfaces 517 and 522 operate in accordance with a PtP communication protocol such as the Intel® QuickPath Interconnect (QPI) or the like. In other embodiments, a different interconnect may be used.

In some embodiments, chipset 520 is operable to communicate with processor 510, 505N, display device 540, and other devices, including a bus bridge 572, a smart TV 576, I/O devices 574, nonvolatile memory 560, a storage medium (such as one or more mass storage devices) 562, a keyboard/mouse 564, a network interface 566, and various forms of consumer electronics 577 (such as a PDA, smart phone, tablet etc.), etc. In one embodiment, chipset 520 couples with these devices through an interface 524. Chipset 520 may also be coupled to a wireless antenna 578 to communicate with any device configured to transmit and/or receive wireless signals. In one example, any combination of components in a chipset may be separated by a continuous flexible shield as described in the present disclosure.

Chipset 520 connects to display device 540 via interface 526. Display 540 may be, for example, a liquid crystal display (LCD), a light emitting diode (LED) array, an organic light emitting diode (OLED) array, or any other form of visual display device. In some embodiments of the example system, processor 510 and chipset 520 are merged into a single SOC. In addition, chipset 520 connects to one or more buses 550 and 555 that interconnect various system elements, such as I/O devices 574, nonvolatile memory 560, storage medium 562, a keyboard/mouse 564, and network interface 566. Buses 550 and 555 may be interconnected together via a bus bridge 572.

In one embodiment, mass storage device 562 includes, but is not limited to, a solid state drive, a hard disk drive, a universal serial bus flash memory drive, or any other form of computer data storage medium. In one embodiment, network interface 566 is implemented by any type of well-known network interface standard including, but not limited to, an Ethernet interface, a universal serial bus (USB) interface, a Peripheral Component Interconnect (PCI) Express interface, a wireless interface and/or any other suitable type of interface. In one embodiment, the wireless interface operates in accordance with, but is not limited to, the IEEE 802.11 standard and its related family, Home Plug AV (HPAV), Ultra Wide Band (UWB), Bluetooth, WiMax, or any form of wireless communication protocol.

While the modules shown in FIG. 5 are depicted as separate blocks within the system 500, the functions performed by some of these blocks may be integrated within a single semiconductor circuit or may be implemented using two or more separate integrated circuits. For example, although cache memory 516 is depicted as a separate block within processor 510, cache memory 516 (or selected aspects of 516) can be incorporated into processor core 512.

### VARIOUS NOTES & EXAMPLES

To better illustrate the method and apparatuses disclosed herein, a non-limiting list of embodiments is provided here:

Example 1 is a semiconductor assembly comprising: a component; a semiconductor die having a semiconductor die pad; and a hybrid bond connecting the semiconductor die to a substrate, wherein the hybrid bond comprises: a via; a first metallic pad at a first end of the via, the first metallic pad bonded to the semiconductor die pad; a dielectric layer surrounding the first metallic pad, the dielectric layer bonded to the semiconductor die around the semiconductor die pad; and a second metallic pad at a second end of the via, the second metallic pad bonded to the component.

In Example 2, the subject matter of Example 1 optionally includes a dielectric material surrounding the via.

In Example 3, the subject matter of any one or more of Examples 1-2 optionally include wherein the via, the first metallic pad, and the second metallic pad comprise copper.

In Example 4, the subject matter of any one or more of Examples 1-3 optionally include wherein the dielectric layer comprises silicon nitride or silicon oxide.

In Example 5, the subject matter of any one or more of Examples 1-4 optionally include wherein the component comprise a substrate.

In Example 6, the subject matter of any one or more of Examples 1-5 optionally include wherein the component comprises an interconnect.

Example 7 is a method of making a semiconductor assembly comprising: making a hybrid bond assembly comprising: depositing a first metallic pad on a surface; encapsulating the first metallic pad with a dielectric material; depositing a dielectric layer on the dielectric material opposite the surface; subsequently removing a portion of the dielectric material and a portion of the dielectric layer to create a cavity over the first metallic pad; filling the cavity with a metallic material to produce a via; and connecting two components through the hybrid bond assembly.

In Example 8, the subject matter of Example 7 optionally includes wherein the surface comprises a substrate.

In Example 9, the subject matter of Example 8 optionally includes depositing a sputter seed layer in the cavity before filling the cavity with the metallic material.

In Example 10, the subject matter of any one or more of Examples 8-9 optionally include wherein filling the cavity with a metallic material comprises plating.

In Example 11, the subject matter of any one or more of Examples 8-10 optionally include planarization of the metallic material after filling the cavity.

In Example 12, the subject matter of any one or more of Examples 8-11 optionally include wherein depositing the dielectric layer is done after encapsulating the first metallic pad.

In Example 13, the subject matter of any one or more of Examples 7-12 optionally include wherein the surface comprises an etch material on a carrier.

In Example 14, the subject matter of Example 13 optionally includes wherein depositing the dielectric layer is done before encapsulating the first metallic pad.

In Example 15, the subject matter of any one or more of Examples 13-14 optionally include removing the carrier and the etch material after filling the cavity.

In Example 16, the subject matter of any one or more of Examples 13-15 optionally include depositing a second metallic pad on the via opposite the first metallic pad.

In Example 17, the subject matter of Example 16 optionally includes building additional layers of dielectric material and via.

In Example 18, the subject matter of any one or more of Examples 7-17 optionally include wherein connecting two components through the hybrid bond assembly comprises bonding a first of the two components to the dielectric layer and bonding the first of the two components to the via through a metal-metal bond.

In Example 19, the subject matter of any one or more of Examples 7-18 optionally include wherein connecting two components through the hybrid bond assembly comprises heating the hybrid bond assembly to create a metal-metal bond between the via and a metallic portion of one of the two components.

Example 20 is a device comprising: a component; a semiconductor die having a semiconductor die pad; and a hybrid bond connecting the semiconductor die to a substrate, wherein the hybrid bond comprises: a via; a first metallic pad at a first end of the via, the first metallic pad bonded to the semiconductor die pad; a dielectric layer surrounding the first metallic pad, the dielectric layer bonded to the semiconductor die around the semiconductor die pad; and a second metallic pad at a second end of the via, the second metallic pad bonded to the component; and a screen.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Although an overview of the inventive subject matter has been described with reference to specific example embodiments, various modifications and changes may be made to these embodiments without departing from the broader scope of embodiments of the present disclosure. Such embodiments of the inventive subject matter may be referred to herein, individually or collectively, by the term “invention” merely for convenience and without intending to voluntarily limit the scope of this application to any single disclosure or inventive concept if more than one is, in fact, disclosed.

The embodiments illustrated herein are described in sufficient detail to enable those skilled in the art to practice the teachings disclosed. Other embodiments may be used and derived therefrom, such that structural and logical substitutions and changes may be made without departing from the scope of this disclosure. The Detailed Description, therefore, is not to be taken in a limiting sense, and the scope of various embodiments is defined only by the appended claims, along with the full range of equivalents to which such claims are entitled.

As used herein, the term “or” may be construed in either an inclusive or exclusive sense. Moreover, plural instances may be provided for resources, operations, or structures described herein as a single instance. Additionally, boundaries between various resources, operations, modules, engines, and data stores are somewhat arbitrary, and particular operations are illustrated in a context of specific illustrative configurations. Other allocations of functionality are envisioned and may fall within a scope of various embodiments of the present disclosure. In general, structures and functionality presented as separate resources in the example configurations may be implemented as a combined structure or resource. Similarly, structures and functionality presented as a single resource may be implemented as separate resources. These and other variations, modifications, additions, and improvements fall within a scope of embodiments of the present disclosure as represented by the appended claims. The specification and drawings are, accordingly, to be regarded in an illustrative rather than a restrictive sense.

The foregoing description, for the purpose of explanation, has been described with reference to specific example embodiments. However, the illustrative discussions above are not intended to be exhaustive or to limit the possible example embodiments to the precise forms disclosed. Many modifications and variations are possible in view of the above teachings. The example embodiments were chosen and described in order to best explain the principles involved and their practical applications, to thereby enable others skilled in the art to best utilize the various example embodiments with various modifications as are suited to the particular use contemplated.

It will also be understood that, although the terms “first,” “second,” and so forth may be used herein to describe various elements, these elements should not be limited by these terms. These terms are only used to distinguish one element from another. For example, a first contact could be termed a second contact, and, similarly, a second contact could be termed a first contact, without departing from the scope of the present example embodiments. The first contact and the second contact are both contacts, but they are not the same contact.

The terminology used in the description of the example embodiments herein is for the purpose of describing particular example embodiments only and is not intended to be limiting. As used in the description of the example embodiments and the appended examples, the singular forms “a,” “an,” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if” may be construed to mean “when” or “upon” or “in response to determining” or “in response to detecting,” depending on the context. Similarly, the phrase “if it is determined” or “if [a stated condition or event] is detected” may be construed to mean “upon determining” or “in response to determining” or “upon detecting [the stated condition or event]” or “in response to detecting [the stated condition or event],” depending on the context.

What is claimed is:

1. A semiconductor assembly comprising:
a component;
a semiconductor die having a semiconductor die pad; and
a hybrid bond connecting the semiconductor die to a substrate, wherein the hybrid bond comprises:
a via that comprises a metal;
a pad that comprises a metal at a first end of the via, the first pad bonded to the semiconductor die pad;
a dielectric layer surrounding the first pad, the dielectric layer bonded to the semiconductor die around the semiconductor die pad; and
a second pad that comprises a metal at a second end of the via, the second pad bonded to the component.

2. The semiconductor assembly of claim 1, further comprising a dielectric material surrounding the via.

3. The semiconductor assembly of claim 1, wherein the via, the first pad, and the second pad comprise copper.

4. The semiconductor assembly of claim 1, wherein the dielectric layer comprises silicon nitride or silicon oxide.

5. The semiconductor assembly of claim 1, wherein the component comprise a substrate.

6. The semiconductor assembly of claim 1, wherein the component comprises an interconnect.

7. A method of making a semiconductor assembly comprising:
making a hybrid bond assembly comprising:
depositing a first pad that comprises a metal on a surface;
encapsulating the first pad with a dielectric material;
depositing a dielectric layer on the dielectric material opposite the surface;
subsequently removing a portion of the dielectric material and a portion of the dielectric layer to create a cavity over the first pad;
filling the cavity with a metal to produce a via; and
connecting two components through the hybrid bond assembly.

8. The method of claim 7, wherein the surface comprises a substrate.

9. The method of claim 8, further comprising depositing a sputter seed layer in the cavity before filling the cavity with the metal.

10. The method of claim 8, wherein filling the cavity with a metal comprises plating.

11. The method of claim 8, further comprising planarization of the metal after filling the cavity.

12. The method of claim 8, wherein depositing the dielectric layer is done after encapsulating the first pad.

13. The method of claim 7, wherein the surface comprises an etch material on a carrier.

14. The method of claim 13, wherein depositing the dielectric layer is done before encapsulating the first pad.

15. The method of claim 13, further comprising removing the carrier and the etch material after filling the cavity.

16. The method of claim 13, further comprising depositing a second pad that comprises a metal on the via opposite the first pad.

17. The method of claim 16, further comprising building additional layers of dielectric material and via.

18. The method of claim 7, wherein connecting two components through the hybrid bond assembly comprises bonding a first of the two components to the dielectric layer and bonding the first of the two components to the via through a metal-metal bond.

19. The method of claim 7, wherein connecting two components through the hybrid bond assembly comprises heating the hybrid bond assembly to create a metal-metal bond between the via and a portion that comprises a metal of one of the two components.

20. A device comprising:
a component;
a semiconductor die having a semiconductor die pad; and
a hybrid bond connecting the semiconductor die to a substrate, wherein the hybrid bond comprises:
a via that comprises a metal;
a first pad that comprises a metal at a first end of the via, the first pad bonded to the semiconductor die pad;
a dielectric layer surrounding the first metallic pad, the dielectric layer bonded to the semiconductor die around the semiconductor die pad; and
a second pad that comprises a metal at a second end of the via, the second pad bonded to the component; and
a screen.
